(19) United States
(12) Patent Application Publication
(10) Pub. No.: US 2002/0100952 A1
(43) Pub. Date: Aug. 1, 2002

(54) Semiconductor device and method of forming isolation area in the semiconductor device

(76) Inventor: Sung-Kwon Hong, Daejeon (KR)

Correspondence Address: BIRCH STEWART KOLASCH & BIRCH, PO BOX 747, FALLS CHURCH, VA, 22040-0747, US

(21) Appl. No.: 09/996,570

(22) Filed: Nov. 30, 2001

(30) Foreign Application Priority Data
Dec. 1, 2000 (KR) 72450/2000

(51) Int. Cl. H01L 21/8238; H01L 29/00

(52) U.S. Cl. 257/510; 438/221; 438/296; 438/353

(57) ABSTRACT

A semiconductor device and method of forming an isolation area in a semiconductor device including forming a trench in a semiconductor substrate and forming an insulating layer inside the trench. A nitrogen ion implantation layer is formed in the semiconductor substrate and the insulating layer using vertical ion implantation having an incident angle perpendicular to a surface of the semi-conductor substrate.

### BACKGROUND OF THE INVENTION

1. Field of the Invention

The present invention relates to a method of fabricating a semiconductor device, and more particularly, to a method of forming an isolation area in a semi-conductor device.

2. Background of the Related Art

Local oxidation of silicon(hereinafter abbreviated LOCOS) has been widely used for forming an isolation area in a semiconductor device. LOCOS fails to exceed the bounds of improving device integration due to the generation of its specific Bird's Beak. In order to fabricate a highly-integrated semiconductor device, STI(shallow trench isolation), PGI(profiled groove isolation) and the like have DRAM fabrication. STI or PGI includes the steps of forming a groove or trench in a semiconductor substrate and filling the groove or trench with an insulator.

Unfortunately, the method of forming a device isolation area by etching a semiconductor substrate such as STI or PGI has some problems. For example, boron ions doping a semiconductor substrate segregate into a device isolation area so that the impurity concentration at an interface between the semiconductor substrate and device isolation area is reduced. As a result, a depletion layer is formed in the semiconductor substrate along the interface. The depletion layer is easily converted into an inversion layer by a minute voltage applied thereto. This causes devices that are separated from each other by the device isolation area to be electrically shorted by the inversion layer formed along the interface between the device isolation area and the semiconductor substrate. Consequently, malfunctions of the semiconductor devices occur.

Many methods are suggested for preventing the formation of the depletion layer along the interface between the device isolation area and semiconductor substrate. One method includes forming a trench in a semiconductor substrate and doping the semiconductor substrate with boron ions excessively along an inner sidewall surface of the trench. In another method, nitrogen ions are implanted in a semiconductor substrate along a sidewall surface inside a trench or a thin nitrogen film is formed on a surface of a semiconductor substrate. This allows the formation of a diffusion barrier layer preventing boron ions in the substrate from diffusing into the device isolation area.

FIG. 1A to FIG. 1F show cross-sectional views of a conventional STI method using ion implantation along a sidewall of a trench by tilted ion-implantation of nitrogen ions.

Referring to FIG. 1A, a pad oxide layer 101 and a nitride layer 102 are formed on an upper surface of a semiconductor substrate 100, successively.

Referring to FIG. 1B, after forming a photoresist pattern 103 on an upper surface of the nitride layer 102, an upper surface of the semiconductor substrate 100 is exposed in part by etching the nitride layer 102 and pad oxide layer 101 successively and using the photoresist pattern 103 as a mask.

Referring to FIG. 1C, a trench 104 is formed by etching the exposed portion of the semiconductor substrate 100.

Referring to FIG. 1D, nitrogen ions are implanted in the substrate 100 along the sidewalls of trench 104. The nitrogen ion implantation is carried out by a tilted ion implantation method having a slope of ‘θ’ from a vertical directional line 108, which is approximately perpendicular to the upper surface of the semiconductor substrate. The tilted ion implantation allows ions to be implanted along the slanted sidewall of the trench 104. Therefore, nitrogen ions are implanted along an entire sidewall surface of trench 104.

Referring to FIG. 1E, a sacrificial oxide layer 105 is formed on an inner wall and a bottom surface of the trench 104 in the semiconductor substrate 100. Also, an oxide layer 106 is formed on an inside of the trench 104 and an entire upper surface of the nitride layer 102. An area designated by a numeral ‘110’ in FIG. 1E is an area where source/drain will be formed after the completion of the device isolation.

Referring to FIG. 1F, the oxide and nitride layers 106 and 102 are removed by CMP(chemical mechanical polishing). The removal reveals and planarizes the upper surface of the semiconductor substrate 100. Thus, the method of forming an isolation area in a semiconductor device by STI is completed.

Unfortunately, in the above-mentioned conventional art method of semiconductor device isolation, resistance of source and/or drain areas is increased by the nitrogen ions implanted into the source/drain formation area 110, despite the benefit of preventing the segregation of nitrogen ions injected into the trench sidewall of the semi-conductor substrate by tilted ion implantation.

### SUMMARY OF THE INVENTION

Accordingly, the present invention is directed to a method of forming an isolation area in a semiconductor device that substantially obviates one or more problems due to limitations and disadvantages of the related art.

An object of the present invention is to provide a method of forming an isolation area in a semiconductor device allowing an improved device reliance by stabilizing an electrical characteristic of a semiconductor device.

Another object of the present invention is to provide an STI method of forming an isolation area in a semiconductor device by implanting nitrogen ions for preventing boron ion segregation into the portion of the semiconductor substrate so as not to implant the nitrogen ions in a surface of the semiconductor substrate where source/drain will be formed.

To achieve these objects and other advantages and in accordance with the purpose of the invention, as embodied and broadly described herein, a method of forming an isolation area in a semiconductor device includes the steps of forming a trench in a semiconductor substrate, forming an insulating layer inside the trench, and forming a nitrogen ion implantation layer in the semiconductor substrate and the insulating layer using vertical ion implantation having an incident angle substantially perpendicular to a surface of the semiconductor substrate.

Preferably, the nitrogen ion implantation layer is formed in the semiconductor substrate and insulating layer at a about half the depth of the trench by implanting the nitrogen ions therein.

Also, as embodied and broadly described herein, a semiconductor device having an isolation area includes a semi-conductor substrate with a trench formed in the semi-conductor substrate; an insulator in the interior of the trench; a source/drain implantation region in the semi-conductor substrate; and an ion implantation in the insulator and the semi-conductor substrate at a depth within the semi-conductor conductor substrate which is lower than the source/drain implantation region.

Further scope of applicability of the present invention will become apparent from the detailed description given hereinafter. However, it should be understood that the detailed description and specific examples, while indicating preferred embodiments of the invention are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1A to FIG. 1F illustrate a conventional art method of forming an isolation structure in a semi-conductor device and

FIG. 2A to FIG. 2F illustrate a method of forming an isolation area according to one embodiment of the present invention.

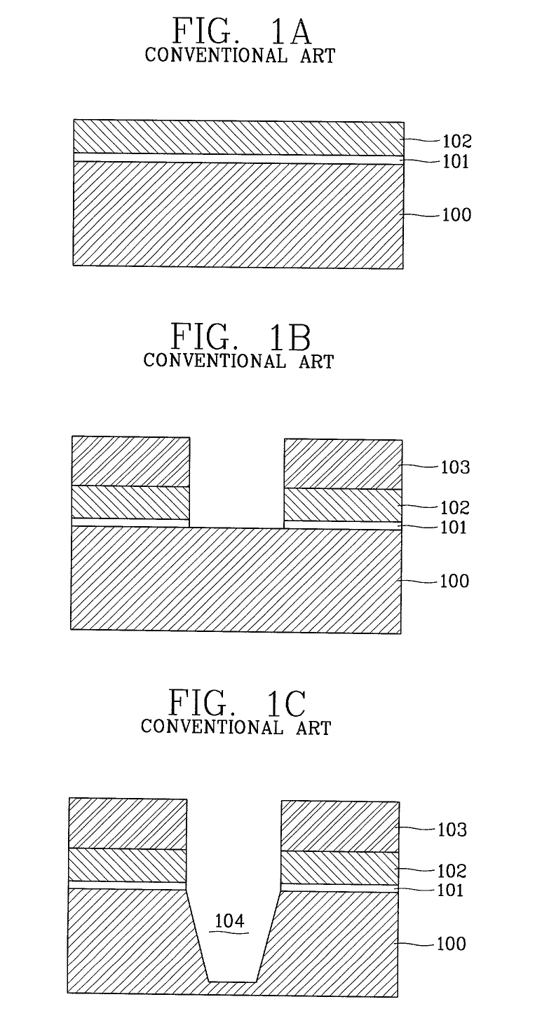

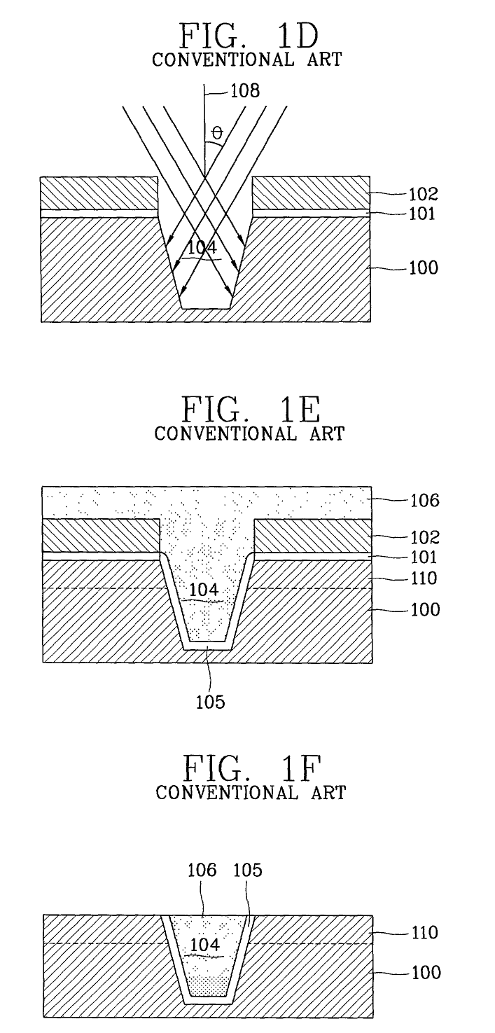

### DETAILED DESCRIPTION OF THE INVENTION

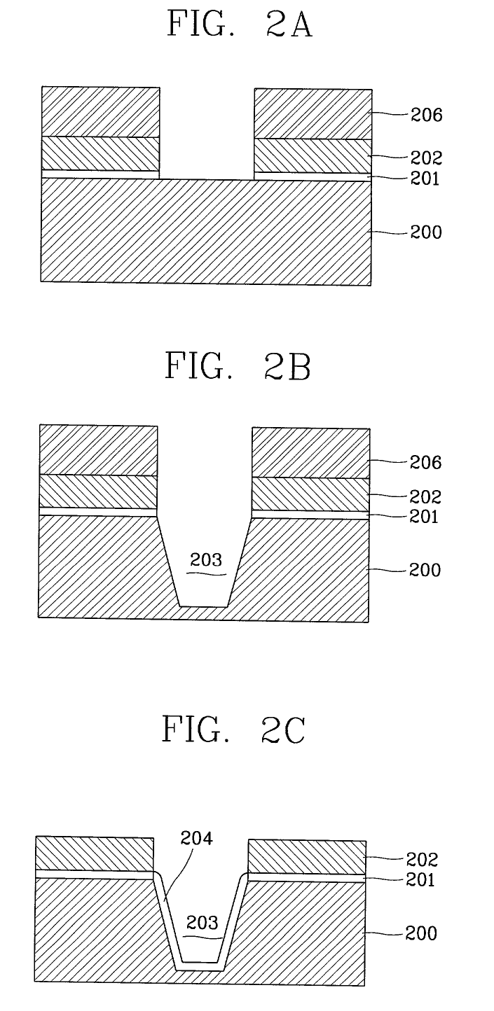

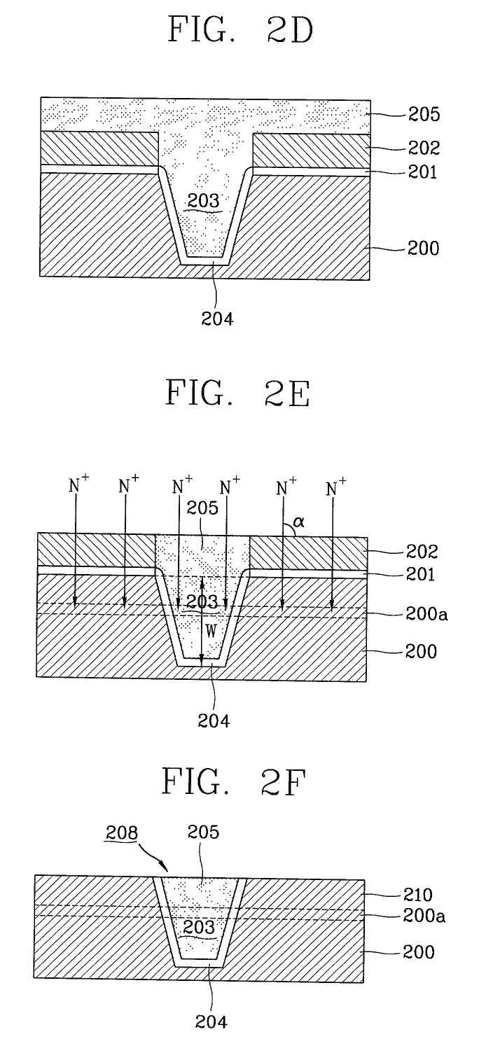

FIG. 2A to FIG. 2F illustrate a method of forming an isolation area according to a preferred embodiment of the present invention.

As shown in FIG. 2F, an isolation area 208 is formed in a semiconductor substrate 200 according to methods well known in the art. The isolation region includes a trench 203 lined with a thermal oxide layer 204 on its sides and an insulating layer 205 therein. The substrate 200 has an ion implantation region 200a. The ion implantation region is located below source/drain implantation region 210.

Referring to FIG. 2A, a pad oxide layer 201 is formed on a semiconductor substrate 200. The pad oxide layer 201 is formed by oxidizing a silicon substrate by thermal oxidation or deposited by CVD(chemical vapor deposition). A silicon nitride layer 202 is deposited on the pad oxide layer 201. A photoresist pattern 206 has been formed on the silicon nitride layer 202, an upper surface of the semi-conductor substrate 200 corresponding to a device isolation area is exposed by selectively etching the silicon nitride layer 202 and the pad(sacrificing) oxide layer 201 using the photoresist pattern 206 as a mask.

Referring to FIG. 2B, a trench 203 is formed in the semiconductor substrate 200 by etching the exposed portion of the semiconductor substrate 200.

Referring to FIG. 2C, the photoresist pattern 206 is removed. A thermal oxide layer 204 about 50 to 200 Å thick is formed on a surface of the semiconductor substrate 200 inside the trench 203 by annealing at about 1050° C. in an atmosphere of O₂. This is performed to restore or recover the damage on the surface of the semiconductor substrate 200 caused by the etch and ion implantation for forming the trench 203. The thermal oxide 204 is also called a sacrificing oxide layer.

Referring to FIG. 2D, an insulating layer 205 is formed inside the trench 203 and on an upper surface of the nitride layer 202 using CVD or other suitable method well known in the art. The insulating layer 205 is preferably formed of silicon oxide but may be formed of other suitable materials.

Referring to FIG. 2E, the insulating layer 205 is polished by performing CMP until the upper surface of the nitride layer 202 is exposed. Other suitable method well known in the art may also be used to remove the insulating layer 205.

A nitrogen ion implantation layer 200a is formed in the semiconductor substrate 200 and insulating layer 205 at a predetermined depth by projecting nitrogen ions vertically inside the semiconductor substrate 200 and the insulating layer 205. According to this embodiment, the nitrogen ions are injected in a substantially vertical direction which has an incidence angle a approximately perpendicular to the surface of the semiconductor substrate 200. However, the nitrogen ions maybe injected at other suitable incidence angles.

It is preferable that the nitrogen ion implantation layer 200a is formed at a predetermined depth which is deeper than the location that the source/drain junctions are to be formed. Specifically, the nitrogen ion implantation layer 200a is more preferably formed at half of the depth W, which is the distance between the surface of the semi-conductor substrate 200 and the bottom of trench 203.

Referring to FIG. 2F, the nitride and pad oxide layers 202 and 201 are removed by CMP(chemical mechanical polishing) or other suitable method well known in the art so as to reveal and planarize the upper surface of the semiconductor substrate 200. Thus, an isolation area in a semiconductor device is formed.

Accordingly, the method of forming the isolation area according to the present invention enhances the prevention of performance degradation of a semi-conductor device by avoiding implanting nitrogen ions near a surface of a source/drain area of a semiconductor substrate.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method of forming an isolation area in a semiconductor device comprising the steps of:
forming a trench in a semiconductor substrate;
forming an insulating layer inside the trench; and
forming a nitrogen ion implantation layer in the semiconductor substrate and the insulating layer using vertical ion implantation having an incident angle substantially perpendicular to a surface of the semi-conductor substrate.

2. The method of claim 1, further comprising a step of: forming a sacrificing oxide layer on a sidewall of the trench.

3. The method of claim 2, wherein the sacrificing oxide layer is formed by annealing the semiconductor substrate at about 1050° C. in an atmosphere of O₂.

4. The method of claim 1, wherein the step of forming an insulating layer inside the trench includes
forming an oxide layer in the trench and on an upper surface of the semiconductor substrate; and
performing chemical mechanical polishing on the oxide layer.

5. The method of claim 4, wherein the oxide layer is formed by chemical vapor deposition.

6. The method of claim 1, wherein
the step of forming a trench in a semi-conductor substrate includes
forming a pad oxide layer on the semi-conductor substrate;
forming a silicon nitride layer on the pad oxide layer;
forming a photoresist pattern on the silicon nitride layer;
exposing a portion of an upper surface of the semiconductor substrate by removing the silicon nitride and pad oxide layers using the photoresist pattern as a mask; and
etching the exposed portion of the semi-conductor substrate to a predetermined depth.

7. The method of claim 1, wherein
the nitrogen ion implantation layer is formed at about half the depth of the trench.

8. A method of forming an isolation area in a semiconductor comprising:
forming a trench in a semiconductor substrate having a source/drain formation rejection;
forming an insulating layer inside the trench; and
forming an ion implantation layer in the semi-conductor substrate and insulating layer at a position below the source/drain formation region.

9. The method of claim 8, wherein
the source/drain formation region is adjacent the upper surface of the semiconductor substrate.

10. The method of claim 8 wherein
the step of forming the ion implantation layer includes forming the ion implantation layer at about one half the distance between a lower surface of the trench and an upper surface of the substrate.

11. The method of claim 8, wherein the step of forming an ion implantation layer includes
performing an ion implantation having an incident angle substantially perpendicular to an upper surface of the semiconductor substrate.

12. The method of claim 8, further comprising a step of:
forming a sacrificing oxide layer on a sidewall of the trench.

13. The method of claim 12, wherein the sacrificing oxide layer is formed by annealing the semi-conductor substrate at about 1050° C. in an atmosphere of O₂.

14. The method of claim 8, wherein
the step of forming an insulating layer inside the trench includes
forming an oxide layer in the trench and on an upper surface of the semiconductor substrate; and
performing chemical mechanical polishing on the oxide layer.

15. The method of claim 14, wherein the oxide layer is formed by chemical vapor deposition.

16. The method of claim 8, wherein
the step of forming a trench in a semi-conductor substrate includes
forming a pad oxide layer on the semi-conductor substrate;
forming a silicon nitride layer on the pad oxide layer;
forming a photoresist pattern on the silicon nitride layer;
exposing a portion of an upper surface of the semiconductor substrate by removing the silicon nitride and pad oxide layers using the photoresist pattern as a mask; and
etching the exposed portion of the semi-conductor substrate to a predetermined depth.

17. The method of claim 8, wherein
the nitrogen ion implantation layer is formed at about half the depth of the trench.

18. A semiconductor device having an isolation area comprising:
a semi conductor substrate;
a trench formed in the semi conductor substrate;
an insulator in the interior of the trench;
a source/drain implantation region in the semi conductor substrate; and
an ion implantation in the insulator and the semi conductor substrate at a depth that is lower than the source/drain implantation region.

19. The device of claim 18, wherein
the depth of the ion implantation is about one half the distance from an upper surface of the semi conductor substrate to a lower surface of the trench.
